(19) United States
(12) Patent Application Publication
(10) Pub. No.: US 2010/0155919 A1
(43) Pub. Date: Jun. 24, 2010

(54) High-density multifunctional PoP-type multi-chip package structure

(75) Inventors: In-Sang Song, Seoul (KR); Ji-Han Ko, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,625

(22) Filed: Nov. 25, 2009

(30) Foreign Application Priority Data
Dec. 19, 2008 (KR) 10-2008-0130264

(51) Int. Cl. H01L 25/065

(52) U.S. Cl. 257/686; 257/690; 257/E25.013

(57) ABSTRACT

Provided is a high-capacity multifunctional multichip package (MCP) structure in which a multifunctional MCP capable of, for example, high-speed image processing and communications, is mounted on a high-capacity memory package capable of storing various data, e.g., moving images, pictures, or music files. The high-capacity memory package may be efficiently applied to a mass storage of a mobile device. However, an eight-stage-plus chip stacking structure should overcome yield loss during assembly and test processes. To do this, a memory package may be divided into a pair of package to form upper and lower package stacks. To physically connect the pair of packages, molding members may be installed opposite each other and fixed to each other using an adhesive member. Also, to electrically connect the pair of packages, one of the packages may be formed using a flexible PCB substrate capable of bending. The flexible PCB substrate of the one of the packages may be connected to both sides of the other of the packages, and the two packages may be thermally bonded to each other under pressure using solder balls and ball lands.

### CROSS-REFERENCE TO RELATED APPLICATION

This application claims priority under 35 USC §119 to Korean Patent Application No. 10-2008-0130264, filed Dec. 19, 2008, in the Korean Intellectual Property Office (KIPO), the entire contents of which are incorporated herein by reference.

### BACKGROUND

1. Field

Example embodiments relate to a high-density high-capacity multifunctional package-on-package (PoP)-type multichip package (MCP) structure in which a multifunctional MCP is mounted on a high-capacity memory package, and more particularly, to an MCP structure in which a high-capacity memory package capable of storing various data, e.g., moving images, pictures, or music files, is combined with a multifunctional MCP capable of, for example, high-speed image processing and communications, to satisfy both miniaturization of electronic devices and multi-functionality of products.

2. Description of Related Art

According to a conventional package stacking technique, a plurality of unit semiconductor chip packages, each including a single semiconductor chip, may be stacked to form a single stack package, thereby increasing a memory capacity per unit mounting area. The package stacking technique is distinguished from a chip stacking technique of stacking a plurality of semiconductor chips to embody a single semiconductor chip package. A typical package to which the chip stacking technique is applied may be a multichip package (MCP).

However, due to the miniaturization and increased functions of electronic appliances, mounting a larger number of semiconductor devices per unit volume has been required. Accordingly, a conventional chip stacking technique or package stacking technique cannot adjust to miniaturization of electronic portable devices and various functions of mobile products.

### SUMMARY

Example embodiments provide a high-density multichip package (MCP) structure by which high-capacity electronic devices may be embodied and a mounting area may be minimized or reduced. Example embodiments also provide a chip-on-chip (COC)-type high-capacity chip stack structure capable of increasing a memory capacity in the same mounting area.

According to example embodiments, a multichip package (MCP) structure may include a first chip-on-chip (COC)-type high-capacity memory chip stack composed of a plurality of vertically stacked semiconductor chips including at least one of a NAND flash memory chip and a NOR flash memory chip; and a second chip-on-chip (COC)-type multifunctional memory chip stack, different from the first COC-type high-capacity memory chip stack, including a plurality of semiconductor chips having different functions from the plurality of semiconductor chips in the first COC-type high-capacity memory chip stack, wherein the first chip stack and the second chip stack are vertically stacked using a package-on-package (PoP) technique.

In example embodiments, the high-capacity memory chip stack may be equally divided between a first package and a second package, and each of the first and second packages may include at least one of the plurality of semiconductor chips mounted on first and second substrates; first and second conductive members configured to electrically connect the at least one of the plurality of semiconductor chips with the corresponding first and second substrates via corresponding first and second bonding wires; and first and second protection members on the corresponding first and second substrates configured to encapsulate the at least one of the plurality of semiconductor chips.

In example embodiments, the first and second protection members of the corresponding first and second packages may be opposite each other and attached to each other using an adhesive member. In example embodiments, the first substrate of the first package may be a flexible printed circuit board (PCB) substrate having a circuit interconnection line and capable of freely bending, and may be configured to electrically connect the first and second packages.

In example embodiments, the first substrate of the first package may further include a connection portion configured to contact both sides of the second substrate of the second package.

In example embodiments, the structure may further include a plurality of first ball lands on an edge of a top surface of the first substrate of the first package; a plurality of second ball lands on a center of a bottom surface of the second substrate of the second package; a plurality of first solder balls in a center of a bottom surface of the first substrate of the first package configured to contact with an external package; and a plurality of second solder balls on an edge of a bottom surface of the second substrate of the second package and configured to contact the first ball lands, wherein the first and second packages may be electrically connected by the second solder balls and the first ball lands and function as a single memory package.

In example embodiments, the structure may further include a third PCB substrate electrically interconnected to each of the plurality of semiconductor chips of the multifunctional memory chip stack via a third bonding wire; a third protection member configured to encapsulate each of the plurality of semiconductor chips; and a plurality of third solder balls on a bottom surface of the third PCB substrate, the third solder balls functioning as external terminals and electrically connected to the second ball lands of the second package. In example embodiments, the multifunctional memory chip stack may have a fan-in structure such that the third solder balls are on the same area as each of the plurality of semiconductor chips of the multifunctional memory chip stack or the third protection member.

According to example embodiments, a multichip package (MCP) structure may include at least one first semiconductor chip divided from an original package memory capacity by a given ratio and stacked on a first substrate; a first protection member molded on the first substrate; at least one second semiconductor chip divided from the original package memory capacity by the remaining ratio and stacked on a second substrate extending to both sides of the first substrate and electrically connected to the first substrate; a second protection member molded on the second substrate and opposite the first protection member; and an adhesive member configured to attach the first and second protection members.

In example embodiments, the second substrate may be a flexible printed circuit board (PCB) capable of bending to pass lateral surfaces of the first and second protection members and configured to contact the first substrate.

The MCP structure may further include at least one of a plurality of first solder balls and a plurality of first ball lands on a bottom surface of the first substrate; and at least one of a plurality of second ball lands and a plurality of second solder balls on a top surface of the second substrate corresponding to at least one of the plurality of first solder balls and the plurality of first ball lands.

In example embodiments, the MCP structure may further include a third PCB substrate electrically interconnected to the at least one second semiconductor chip; a third protection member configured to encapsulate the at least one second semiconductor chip; and a plurality of third solder balls on a bottom surface of the third PCB substrate, the third solder balls functioning as external terminals and electrically connected to the at least one of the plurality of second ball lands and the plurality of second solder balls.

### BRIEF DESCRIPTION OF THE DRAWINGS

Example embodiments are described in further detail below with reference to the accompanying drawings. It should be understood that various aspects of the drawings may have been exaggerated for clarity.

FIG. 1 is a cross-sectional view of an eight-stage multichip package (MCP) structure in which 8 semiconductor chips are stacked, according to example embodiments;

FIG. 2 is a cross-sectional view of a sixteen-stage MCP structure in which 16 semiconductor chips are stacked, according to example embodiments;

FIG. 3 is a cross-sectional view of an MCP structure according to example embodiments; and

FIG. 4 is a cross-sectional view illustrating a process of assembling an MCP according to example embodiments.

### DETAILED DESCRIPTION OF EXAMPLE EMBODIMENTS

Various example embodiments will now be described more fully with reference to the accompanying drawings in which some example embodiments are shown. In this regard, example embodiments may have different forms and should not be construed as being limited to the descriptions set forth herein. Accordingly, example embodiments are merely described below, by referring to the figures, to explain aspects of the present description. In the drawings, the thicknesses of layers and regions are exaggerated for clarity. Like reference numerals refer to the like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Owing to an increase in memory capacity required for data processing, high-density semiconductor memory devices have been required. Thus, various methods for applying high-density semiconductor memory devices to systems have been proposed. A package including a high-density single chip may be employed. Second, a plurality of low-density packages may be employed. Hereinafter, the latter method will be described. When a plurality of low-density packages are used, a mounting area of a system may be increased, thus reducing product competitiveness. In order to minimize or reduce the mounting area of the system, a method of fabricating a multichip package (MCP), by which a plurality of low-density chips are mounted in a single package, may be required.

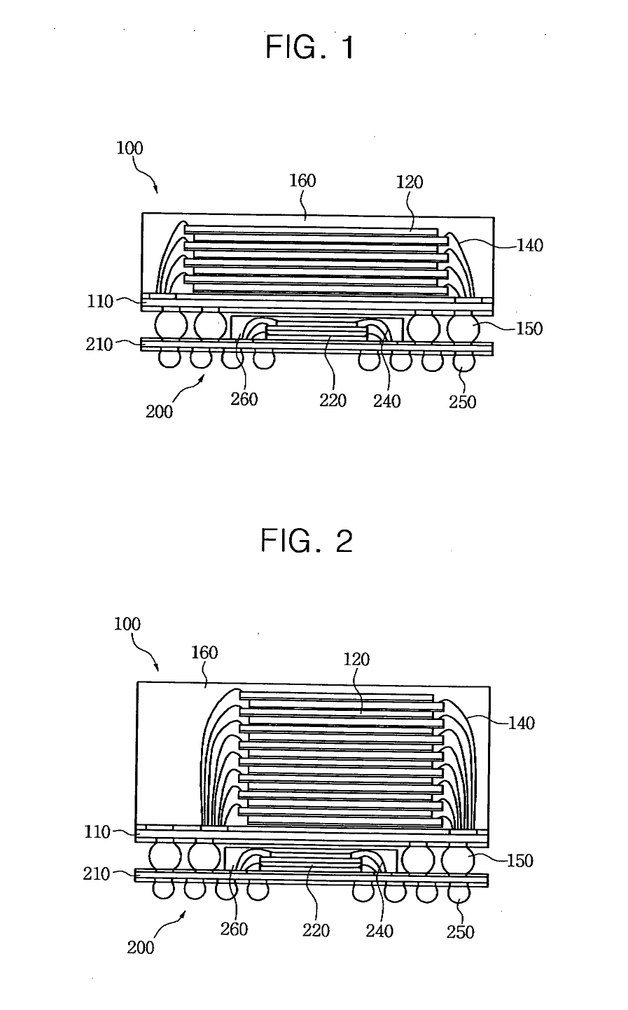

FIG. 1 is a cross-sectional view of an eight-stage MCP structure in which 8 semiconductor chips are stacked, according to example embodiments, and FIG. 2 is a cross-sectional view of a sixteen-stage MCP structure in which 16 semiconductor chips are stacked, according to example embodiments. Referring to FIGS. 1 and 2, an upper memory package 100 with a high capacity may include a plurality of memory semiconductor chips 120 vertically stacked on an upper printed circuit board (PCB) substrate 110 using a chip-on-chip (COC) technique. Although the embodiments shown in FIGS. 1 and 2 describe stackable memory semiconductor chips 120 of the same type, different kinds of memory semiconductor chips may be stacked in a memory package. For example, a memory may be a single memory stack including a volatile memory, e.g., a dynamic random access memory (DRAM) or a static RAM (SRAM), or a flash memory, e.g., a NAND flash memory or a NOR flash memory, or a complex memory stack including a combination thereof.

Each of the memory semiconductor chips 120 may be electrically interconnected to the upper PCB substrate 110 using a bonding wire 140. Solder balls 150 may be attached to a bottom surface of the upper PCB substrate 110 so that each of the memory semiconductor chips 120 may be electrically connected to an external apparatus. The stacked semiconductor chips 120 may be electrically connected to one another using a through silicon via (TSV) forming technique. A protection member 160 may be molded on the upper PCB substrate 110 to protect the semiconductor chips 120 and the bonding wires 140.

As shown in FIGS. 1 and 2, a lower memory package 200 having a different function may be disposed under the upper memory package 100. The lower memory package 200 may be connected to the upper memory package 100 using a package-on-package (PoP) technique. For example, the upper memory package 100 is a storage memory package capable of storing various files, e.g., moving images, to the highest degree, while the lower memory package 200 is a functional memory package capable of, for example, allowing an image to be processed at a higher speed. A plurality of memory semiconductor chips 120 are not packaged as a single package but divided between the upper and lower memory packages 100 and 200 because the upper and lower memory packages 100 and 200 are intended to have different functions and the single package may reduce yield.

Accordingly, because the upper memory package 100 mainly functions as a storage memory device, the number of stacked semiconductor chips 120 of the upper memory package 100 must be larger than that of stacked semiconductor chips of the lower memory package 200.

The solder balls 150 attached to the upper PCB substrate 110 may be adhered or attached to and mounted on a ball land region of a lower PCB substrate 210. The lower memory package 200 may include a plurality of functional semiconductor chips 220 stacked on the lower PCB substrate 210. Similarly, the functional semiconductor chips 220 may be connected to the lower PCB substrate 210 using bonding wires 240 and molded with a protection member 260. Although not shown in the drawings, a plurality of vias (not shown) may be formed in the lower PCB substrate 210. The vias may be filled with a conductive member (not shown) to connect the semiconductor chips 220 with an external module substrate. Also, the lower memory package 200 may be in contact with the external module substrate using lower solder balls 250.

Thus, a plurality of semiconductor chips are stacked in a package system, thereby inhibiting an increase in a mounting area. However, in the above-described COC-type semiconductor-chip stacking structure, yield loss occurs during assembly and test processes. That is, as compared with the eight-stage MCP structure, the sixteen-stage MCP structure may reduce a mounting area, and the sixteen-stage MCP structure may result in reliability degradation and yield loss. According to example embodiments, a method of fabricating an MCP structure that ensures reliability, prevents or reduces yield loss, and also increases a mounting area is proposed.

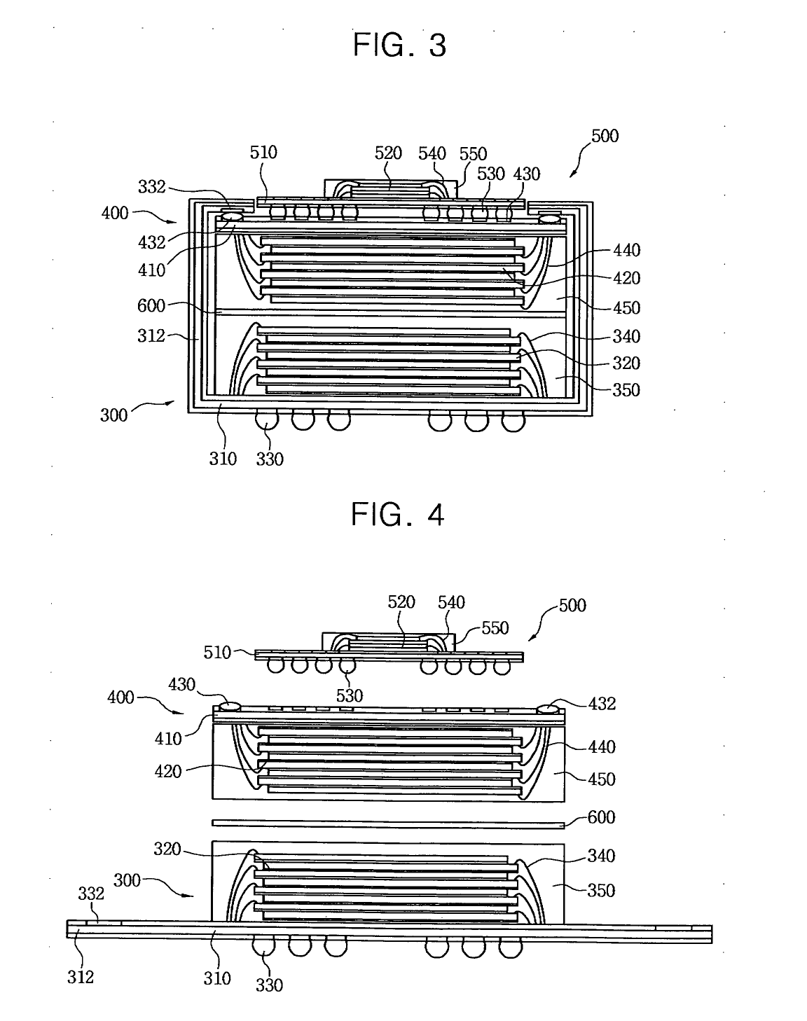

In a PoP-type high-capacity multifunctional MCP structure according to example embodiments, a storage memory package may be divided into two packages. FIG. 2 illustrates the sixteen-stage chip stacking structure in which sixteen memory semiconductor chips 120 are mounted in the upper memory package 100, and FIGS. 3 and 4 illustrate two eight-stage chip stacking structures between which sixteen memory semiconductor chips are equally divided. Thus, the memory semiconductor chips may be mounted in first and second packages 300 and 400. The first package 300 may include a plurality of first semiconductor chips 320 stacked on a first substrate 310 to form a first chip stack, while the second package 400 may include a plurality of second semiconductor chips 420 stacked on a second substrate 410 to form a second chip stack.

A circuit interconnection line (not shown) may be formed on the first substrate 310 of the first package 300 so that the first substrate 310 may serve as a PCB. A pad (not shown) may be disposed on a bottom surface of the first substrate 310, and a plurality of solder balls 330 or conductive bumps, which function as external terminals, may be attached to the pad.

A plurality of first semiconductor chips 320 may be sequentially stacked using an adhesive (not shown) on the first substrate 310 to form the first chip stack. According to example embodiments, an original memory capacity is divided into two equal parts so that each of the two parts may be packaged. However, in other example embodiments, the original memory capacity may be divided into four or more equal parts so that the equal parts may be connected and packaged. In example embodiments, the plurality of first semiconductor chips 320 stacked on the first substrate 310 may be memory chips of the same kind, e.g., NAND flash memory chips or NOR flash memory chips, which may be able to store a larger amount of data. However, different kinds of semiconductor chips or a combination of the same kind of semiconductor chips and different kinds of semiconductor chips may be used instead.

The first substrate 310 may be electrically connected to each of the plurality of first semiconductor chips 320 of the first chip stack by a first bonding wire 340 or another conductive member. Also, a first protection member 350 for protecting the plurality of first semiconductor chips 320 and the first bonding wire 340 may be formed on a top surface of the first substrate 310 using a molding process. For example, the first protection member 350 may be formed of an epoxy mold compound (EMC). However, because a top surface of the first protection member 350 must correspond to a protection member of another package as described later, the top surface of the first protection member 350 may be planarized and molded according to a specific standard if possible.

Because the second package 400 has about the same construction as the first package 300 except for a second substrate 410, a description of the second substrate 410, the second chip stack, the second bonding wire 440, and a second protection member 450 of the second package 400 will be omitted here. The first and second protection members 350 and 450 may be physically fixed using an adhesive member 600.

The first substrate 310 of the first package 300 may be a flexible printed circuit board (PCB) that is capable of freely bending. The length of the first substrate 310 may be greater than the length of a typical package. Thus, the first substrate 310 may further include a connection portion 312 that extends to a greater length than at least the thickness of the package. The connection portion 312 may extend from both sides of the first substrate 310 of the first package 300. Also, when a pair of packages are bonded opposite to each other, the connection portion 312 may be connected to both sides of the second package 400.

Because an edge of a bottom surface of the second substrate 410 of the second package 400 has a ball grid array (BGA) shape, a plurality of second solder balls 432 formed on the bottom surface of the second substrate 410 may function as external terminals connected to the connection portion 312 of the first package 300. Thus, a plurality of first ball lands 332 may be disposed on a top surface of the first substrate 310 of the first package 300 and brought into contact and combined with the second solder balls 432 using a thermal compression bonding process. Thus, the first and second packages 300 and 400 are electrically connected to each other by the first ball lands 332 and the second solder balls 432, so that the first and second packages 300 and 400 may function as a single package.

On the other hand, the second substrate 410 of the second package 400 may include only pads of a plurality of second ball lands 430 without any solder balls. Thus, the center of the bottom surface of the second substrate 410 of the second package 400 may have a land grid array (LGA) shape. As will be described in further detail below, when a multifunctional memory package 500 is packaged to have a fan-in structure, a larger number of pins may be formed as compared with a package having a fan-out structure, so that the number of the second ball lands 430 corresponding to the pins may also increase.

Although it is described that the first ball lands 332 are disposed on the top surface of the first substrate 310 of the first package 300 and the second solder balls 432 are disposed on the bottom surface of the second substrate 410 of the second package 400 and bonded with the first ball lands 332, example embodiments are not limited thereto. In example embodiments, a ball land may be disposed on the bottom surface of the second substrate 410 of the second package 400, and a solder ball may be disposed on the top surface of the substrate 310 of the first package 300. In addition, although it is described that the first substrate 310 of the first package 300 is a flexible PCB and has the connection portion 312 connected to the second substrate 410 of the second package 400, example embodiments are not limited thereto. In example embodiments, the second substrate 410 of the second package 400 may be a flexible PCB. According to example embodiments, the multifunctional memory package 500 may be mounted on high-capacity memory packages 300 and 400.

The multifunctional memory package 500 may include a plurality of multifunctional semiconductor chips 520 stacked on a top surface of a third PCB substrate 510 to form a third chip stack. A plurality of third solder balls 530 may be disposed on a bottom surface of the third substrate 510 so that the multifunctional memory package 500 may be connected to the underlying high-capacity memory packages 300 and 400 by the third solder balls 530. Each of the multifunctional semiconductor chips 520 may be interconnected to the third PCB substrate 510 by a third bonding wire 540 or another third conductive member and molded with a third protection member 550.

Although not shown in the drawings, the high-capacity memory package 300 or 400 or the multifunctional memory package 500 may further include a controller to embody an embedded memory card that may reduce the time and cost required to develop an additional controller or software. Also, a high-capacity NAND flash memory may be applied to the embedded memory card.

A structure in which a solder ball is disposed on the same area as a semiconductor chip is referred to as a fan-in structure, while a structure in which a solder ball is partially attached to a substrate that extends to an outer portion of a semiconductor chip is referred to as a fan-out structure. The lower memory package 200 of FIGS. 1 and 2 must have a fan-out shape such that the solder balls 150 of the high-capacity memory package 100 are attached to the lower memory package 200. However, when the multifunctional memory package 500 is disposed on the high-capacity memory packages 300 and 400 as shown in FIG. 3, the multifunctional memory package 500 may have any one of a fan-out structure and a fan-in structure. Accordingly, the third solder balls 530 may have a relatively small size, and a large number of pins may be formed.

It will be understood that although the terms “top surface”, “bottom surface”, “first”, and “second” may be used herein for brevity, directions or positions of regions or layers should not be limited by these terms. Thus, “front surface”, “rear surface”, “one”, and “another” may be used instead of them.

Hereinafter, a process of fabricating and assembling an MCP will be described with reference to FIG. 4. Specifically, as shown in FIG. 4, a multifunctional memory package 500 and high-capacity memory packages 300 and 400 may be respectively formed.

The multifunctional memory package 500 may include the multifunctional semiconductor chips 520 stacked on the third PCB substrate 510 in an appropriate number for a required function to form the third chip stack. The multifunctional semiconductor chips 520 may be fixed on the third PCB substrate 500 using an adhesive. Each of the multifunctional semiconductor chips 520 may be electrically interconnected to the third PCB substrate 510 using a third bonding wire 540 or other conductive member. A protection member 550 formed of epoxy or another molding material may be formed on the third PCB substrate 510 to encapsulate at least the multifunctional semiconductor chips 520 and the third bonding wire 540. In example embodiments, the third solder balls 530 may be attached to the bottom surface of the third PCB substrate 510 and connected to the high-capacity memory packages 300 and 400.

The high-capacity memory packages 300 and 400, which are required to embody a high-capacity NAND flash memory or a high-capacity NOR flash memory, may equally divide semiconductor chips therebetween and package the divided semiconductor chips using the respective substrates 310 and 410. The plurality of first semiconductor chips 320 may be stacked on the first substrate 310 and fixed on the first substrate 310 using an adhesive to form the first chip stack. Similarly, the plurality of second semiconductor chips 420 may be stacked and fixed on the second substrate 410 using an adhesive to form the second chip stack. The plurality of first semiconductor chips 320 may be electrically interconnected to the first substrate 310 using the first bonding wire 340, and the plurality of second semiconductor chips 420 may be electrically interconnected to the second substrate 410 using the second bonding wire 440. Also, the first protection member 350 may be molded on the first substrate 310 to encapsulate the plurality of first semiconductor chips 320 and the first bonding wire 340. Similarly, the second protection member 450 may be molded on the second substrate 410 to encapsulate the plurality of second semiconductor chips 420 and the first bonding wire 340. As a result, the first and second packages 300 and 400 may be completed.

In example embodiments, before the first and second packages 300 and 400 are completed, the first and second solder balls 330 and 432 and the first and second ball lands 332 and 430, which function as external terminals, may be formed during the preparation of the first and second substrates 310 and 410. For example, the first solder balls 330 may be formed on the bottom surface of the first substrate 310, and the first ball lands 332 may be formed on a top surface of the extended connection portion 312. The second solder balls 432 may be formed on the edge of the bottom surface of the second substrate 410 that is connected to the first substrate 310, and the second ball lands 430 may be formed on a region on which the multifunctional memory package 500 is mounted.

When the multifunctional memory package 500 and a pair of high-capacity memory packages 300 and 400 are completed, they may be assembled as follows. The second package 400 may be stacked on the first protection member 350 of the first package 300. The second protection member 450 of the second package 400 may be disposed opposite the first protection member 350 of the first package 300. The first and second protection members 350 and 450 may be physically fixed using an adhesive member 600. The stacked first and second packages 300 and 400 may be located such that a bottom surface of the second package 400 faces upward. The multifunctional memory package 500 may be stacked on the bottom surface of the second package 400. The third solder balls 530 attached to the bottom surface of the multifunctional memory package 500 may be connected to the second ball lands 430 formed on the bottom surface of the second package 400 using a reflow process.

The connection portion 312 of the first substrate 310 of the first package 300 may be bent, pass the first and second protection members 350 and 450, and be bent again to overlap both sides of the second substrate 410 of the second package 400. The first ball lands 332 formed on the connection portion 312 of the first substrate 310 may be connected to the second solder balls 432 of the second substrate 410 using a thermal compression bonding process.

After the assembly of the multifunctional memory package 500 and the high-capacity memory packages 300 and 400 is finished, a product may be completed through a final test process. Accordingly, yield loss may be inhibited during the assembly and test processes.

As described above, when at least two eight-stage memory chip stacking structures are stacked to form at least a sixteen-stage memory chip stacking structure, yield loss may be prevented or reduced during assembly and test processes. To do this, semiconductor chips to be packaged on a single substrate may be halved and packaged in two separate packages. To physically connect a pair of packages, molding members may be installed opposite each other and fixed to each other using an adhesive member. Also, to electrically connect the pair of packages, one of the packages may be formed using a flexible PCB substrate capable of freely bending and spreading. The flexible PCB substrate of the one of the packages may extend to both sides of the other of the packages, and the two packages may be thermally bonded to each other under pressure using solder balls and ball lands.

As explained thus far, a PoP-type MCP structure may be realized by mounting a multifunctional MCP capable of, for example, high-speed image processing and communications, on a high-capacity memory package capable of storing various data, e.g., moving images, pictures, or music files, and the performance and functions of electronic devices may be increased.

Eight-stage, sixteen-stage, or thirty-two-stage semiconductor chip stacking structures may be formed so that a high-capacity memory chip may be formed on the same mounting area, and electronic devices to which the high-capacity memory chip is applied may function as mass storage.

A memory package may be divided into a pair of packages to form upper and lower package stacks. Thus, yield may be increased during assembly and test processes. In example embodiments, molding members may be installed opposite each other and fixed to each other using an adhesive member, thereby physically connecting the pair of packages. Also, one of the packages may be formed using a flexible PCB substrate, which may be connected to both sides of the other of the packages, so that the pair of packages may be electrically connected to each other.

A multifunctional MCP may be formed on a high-capacity memory package so that the multifunctional MCP may have not only a fan-out structure in which a solder-ball region extends to be wider than a semiconductor chip and a molding member, but also a fan-in structure in which the solder ball region is disposed in the same area as the semiconductor chip and the molding member.

While example embodiments have been disclosed herein, it should be understood that other variations may be possible. Such variations are not to be regarded as a departure from the spirit and scope of example embodiments of the present application, and all such modifications as would be obvious to one skilled in the art are intended to be included within the scope of the following claims.

What is claimed is:

1. A multichip package (MCP) structure comprising:
a first chip stack composed of a plurality of semiconductor chips including at least one of a NAND flash memory chip and a NOR flash memory chip; and
a second chip stack, different from the first chip stack, including a plurality of semiconductor chips having different functions from the plurality of semiconductor chips in the first chip stack,
wherein the first chip stack and the second chip stack are stacked using a package-on-package (PoP) technique,
wherein the first chip stack is equally divided between a first package and a second package,
wherein each of the first and second packages comprises:
at least one of the plurality of semiconductor chips mounted on first and second substrates;
first and second conductive members configured to electrically connect the at least one of the plurality of semiconductor chips with the corresponding first and second substrates via corresponding first and second bonding wires; and
first and second protection members on the corresponding first and second substrates configured to encapsulate the at least one of the plurality of semiconductor chips,
wherein the first and second protection members of the corresponding first and second packages are opposite each other and attached to each other using an adhesive member,
wherein the first substrate of the first package is a flexible printed circuit board (PCB) substrate having a circuit interconnection line and capable of freely bending, and is configured to electrically connect the first and second packages.

2. The structure of claim 1, wherein the first substrate of the first package further comprises:
a connection portion configured to contact both sides of the second substrate of the second package.

3. The structure of claim 2, further comprising:
a plurality of first ball lands on an edge of a top surface of the first substrate of the first package;
a plurality of second ball lands on a center of a bottom surface of the second substrate of the second package;
a plurality of first solder balls in a center of a bottom surface of the first substrate of the first package configured to contact with an external package; and
a plurality of second solder balls on an edge of a bottom surface of the second substrate of the second package and configured to contact the first ball lands,
wherein the first and second packages are electrically connected by the second solder balls and the first ball lands and function as a single memory package.

4. The structure of claim 3, further comprising:
a third PCB substrate electrically interconnected to each of the plurality of semiconductor chips of the second memory chip stack via a third bonding wire;
a third protection member configured to encapsulate each of the plurality of semiconductor chips; and
a plurality of third solder balls on a bottom surface of the third PCB substrate, the third solder balls functioning as external terminals and electrically connected to the second ball lands of the second package.

5. The structure of claim 4, wherein the second memory chip stack has a fan-in structure such that the third solder balls are on the same area as each of the plurality of semiconductor chips of the second memory chip stack or the third protection member.

6. A multichip package (MCP) structure comprising:
at least one first semiconductor chip divided from an original package memory capacity by a given ratio and stacked on a first substrate;
a first protection member molded on the first substrate;
at least one second semiconductor chip divided from the original package memory capacity by the remaining ratio and stacked on a second substrate extending to both sides of the first substrate and electrically connected to the first substrate;
a second protection member molded on the second substrate and opposite the first protection member; and
an adhesive member configured to attach the first and second protection members.

7. The MCP structure of claim 6, wherein the second substrate is a flexible printed circuit board (PCB) capable of bending to pass lateral surfaces of the first and second protection members and configured to contact the first substrate.

8. The MCP structure of claim 7, further comprising:
at least one of a plurality of first solder balls and a plurality of first ball lands on a bottom surface of the first substrate; and
at least one of a plurality of second ball lands and a plurality of second solder balls on a top surface of the second substrate corresponding to at least one of the plurality of first solder balls and the plurality of first ball lands.

9. The MCP structure of claim 8, further comprising:
a third PCB substrate electrically interconnected to the at least one second semiconductor chip;
a third protection member configured to encapsulate the at least one second semiconductor chip; and
a plurality of third solder balls on a bottom surface of the third PCB substrate, the third solder balls functioning as external terminals and electrically connected to the at least one of the plurality of second ball lands and the plurality of second solder balls.
